(19) United States
(12) Patent Application Publication
(10) Pub. No.: US 2015/0076572 A1
(43) Pub. Date: Mar. 19, 2015

(54) SEMICONDUCTOR DEVICE

(71) Applicants: Katsuyuki Sakurano, Hyogo (JP); Hirobumi Watanabe, Hyogo (JP); Takaaki Negoro, Osaka (JP); Katsuhiko Aisu, Hyogo (JP); Kazuhiro Yoneda, Osaka (JP)

(72) Inventors: Katsuyuki Sakurano, Hyogo (JP); Hirobumi Watanabe, Hyogo (JP); Takaaki Negoro, Osaka (JP); Katsuhiko Aisu, Hyogo (JP); Kazuhiro Yoneda, Osaka (JP)

(73) Assignee: RICOH COMPANY, LTD., Tokyo (JP)

(21) Appl. No.: 14/482,092

(22) Filed: Sep. 10, 2014

(30) Foreign Application Priority Data
Sep. 13, 2013 (JP) 2013-190947

(51) Int. Cl. H01L 27/146

(52) U.S. Cl. CPC H01L 27/1463; H01L 27/14643
USPC 257/291; 257/446; 257/438

(57) ABSTRACT

A semiconductor device includes a semiconductor substrate, a plurality of photoelectric conversion elements arranged on the semiconductor substrate to collectively form an image sensor, a plurality of trenches each formed between the photoelectric conversion elements adjacent to each other, and a plurality of impurity diffusion layers each provided at a bottom of the trench at a position deeper than a p-n junction of the photoelectric conversion element.

### CROSS-REFERENCE TO RELATED APPLICATIONS

This patent application is based on and claims priority pursuant to 35 U.S.C. §H 9(a) to Japanese Patent Application No. 2013-190947, filed on Sep. 13, 2013, in the Japan Patent Office, the entire disclosure of which is hereby incorporated by reference herein.

### BACKGROUND

1. Technical Field

The present invention generally relates to a semiconductor device, and more specifically, to a semiconductor device having an image sensor formed by arraying photoelectric conversion elements on a semiconductor substrate.

2. Description of the Related Art

In a semiconductor device using a semiconductor substrate, there is known an image sensor formed by two-dimensionally arranging photoelectric conversion elements. As such an image sensor, there is already known one with a structure where a pair of a photoelectric conversion element and a transistor constitutes a pixel, and the pixels adjacent to each other are separated by a silicon oxide film.

However, there has been a problem with the conventional image sensor in that photo-charges generated by incident light are mixed between the adjacent pixels.

### SUMMARY

A semiconductor device includes a semiconductor substrate, a plurality of photoelectric conversion elements arranged on the semiconductor substrate to collectively form an image sensor, a plurality of trenches each formed between the photoelectric conversion elements adjacent to each other, and a plurality of impurity diffusion layers each provided at a bottom of the trench at a position deeper than a p-n junction of the photoelectric conversion element.

### BRIEF DESCRIPTION OF THE SEVERAL VIEWS OF THE DRAWINGS

FIG. 1 is a schematic sectional view of a semiconductor device according to an example embodiment of the present invention;

FIGS. 2 and 3 are a sectional view for explaining operation of a manufacturing the semiconductor device of FIG. 1;

FIG. 4 is a schematic sectional view for explaining another example of a semiconductor device;

FIG. 5 is a schematic sectional view for explaining still another example of a semiconductor device;

FIG. 6 is a schematic sectional view for explaining another example of a semiconductor device;

FIG. 7 is a schematic sectional view for explaining still another example of a semiconductor device; and

FIG. 8 is a schematic sectional view for explaining still another example of a semiconductor device.

### DETAILED DESCRIPTION

Examples of a semiconductor device having the photoelectric conversion elements that arc two-dimensionally arranged, include a solid-state imaging device such as a complementary metal-oxide-semiconductor (CMOS) sensor and a charge coupled device (CCD) sensor.

The CMOS sensor has a configuration where the photodiode is used as the photoelectric conversion element and its signal is selectively output by a MOS field-effect transistor (MOSFET) installed in each pixel. Therefore, the CMOS sensor has a characteristic of being capable of fabricating all constitutional elements such as the photoelectric conversion element, an output selection switch for each pixel and a peripheral circuit on the same substrate by a general CMOS semiconductor process. Then, as a process rule is made finer, a resolution of the CMOS sensor has been enhanced by reducing dimensions of each pixel.

The photodiode as the photoelectric conversion element is formed by a p-n junction. Generally, in the photodiode, a reversed bias voltage is applied to the p-n junction, to expand a depletion layer. A wavelength of light convertible to electric charges is determined based on a width of the depletion layer.

In the photodiode, the p-n junction is formed in a vertical direction to the semiconductor substrate. The depletion layer spreads in a depth direction of the substrate. Light incident on the photodiode is subjected to photoelectric conversion in a deep portion of the semiconductor substrate.

A direction of the light incident on the photodiode is not only vertical to the pixel, but some of the light have certain inclination. Accordingly, electric charges generated by the light may be output to a pixel next to the pixel where the light has been incident, depending on the location where the electric charges generate. As pixels are made finer, such mixture of pixel outputs tends to occur.

In view of the above, the semiconductor device in the following examples uses a trench, such as a deep trench, as a structure for separating the photoelectric conversion elements in the image sensor.

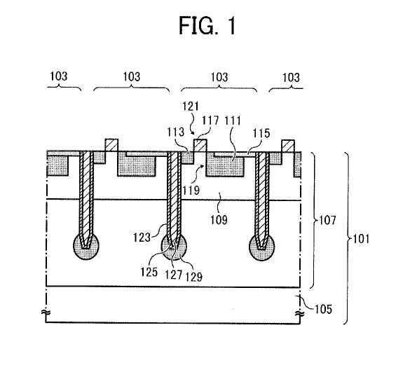

FIG. 1 is a schematic sectional view for explaining an example semiconductor device. In this example, the p-n junction photodiode is provided as a photoelectric conversion element.

A plurality of pixels 103 of a CMOS image sensor are formed on a semiconductor substrate 101. The pixel 103 has a plane dimension of about 2.5×2.5 μm (micrometers), for example.

In this example. the semiconductor sub, rate 101 is formed of silicon. More specifically, the semiconductor substrate 101 includes a p+ silicon substrate 105, and a p-type silicon layer 107 formed on the p-r silicon substrate 105. The p+ silicon substrate 105 is a silicon substrate introduced with p-type impurities with a higher concentration as compared to the p-type silicon layer 107. The p-type silicon layer 107 is a silicon layer formed by epitaxial growth. A thickness of the p-type silicon layer 107 is from 10 to 20 μm, for example.

A p-type well 109 is formed on the surface side of the p-type silicon layer 107. A concentration of the p-type impurities in the p-type well 109 is higher than a concentration of the p-type impurities in the p-type silicon layer 107. A substantial concentration of the p-type impurities in the p-type well 109 is 1×10¹⁷ cm⁻¹, for example. Further, a depth of the p-type well 109 is from 1 to 2 μm, for example.

An n+ diffusion layer 111, an n+ diffusion layer 113 and a p+ diffusion layer 15 are formed on the surface side of the p-type well 109 with respect to each pixel 103. In the pixel 103, the n+ diffusion layer 111 and the n+ diffusion layer 113 are arranged having an interval therebetween. The n diffusion layer 111 is formed deeper than the n+ diffusion layer 113. A substantial concentration of n-type impurities in the n+ diffusion layer 111 and the n+ diffusion layer 113 is 5×10²⁰cm⁻³, for example. Further, a depth of the n+ diffusion layer 111 is from 200 to 300 nm (nanometers), for example.

The p+ diffusion layer 115 is formed as overlapping with a region where the n+ diffusion layer 111 is formed. The p+ diffusion layer 115 is formed at a position shallower than the n+ diffusion layer 111. A substantial concentration of the p-type impurities in the p+ diffusion layer 115 is higher than the concentration of the p-type impurities in the p-type well 109.

A gate electrode 117 is formed above the p-type well 109 between the n+ diffusion layer 111 and the n+ diffusion layer 113, via a gate insulating film. The p+ diffusion layer 115 is arranged having an interval with the gate electrode 117.

The pixel 103 is formed with a p-n junction photodiode 119 (photoelectric conversion element) having the p-type well 109 and the n diffusion layer 111. The p-type well 109 constitutes an anode of the p-n junction photodiode 119. The n+ diffusion layer 111 constitutes a cathode of the p-n junction photodiode 119. The p+ diffusion layer 115 functions as a protective layer for the surface of the p-n junction photodiode 119. The p-type silicon layer 107 and the p+ silicon substrate 105 function as a common anode in the respective p-n junction photodiode 119 in the plurality of pixels 103. The p-n junction photodiode 119 is provided with a p-n junction between the p-type well 109 and the n+ diffusion layer 11.

Further, the pixel 103 is formed with a transistor 121 made of a MOSFET having the n+ diffusion layer 111, the n+ diffusion layer 113 and the gate electrode 117. The transistor 121 functions as an output selection switch of the pixel 103.

A trench 123 is formed in the semiconductor substrate 101 o as to surround a periphery of the pixel 103. The trench 123 separates the adjacent pixels 103. Further, the trench 123 separates the adjacent p-n junction photodiodes 119. A semiconductor material 127 is embedded in the trench 123 via the insulating film 125. The insulating film 125 is a silicon oxide film, for example. The semiconductor material 127 is polysilicon, for example.

For example, the trench 123 is formed at a larger depth than the p-type well 109. A bottom of the trench 123 is arranged in the p-type silicon layer 107 at a position having an interval with the p-type well 109, namely a position deeper than the p-n junction in the p-n junction photodiode 119. The depth of the trench 123 is from 3.0 to 5.0 μm from the surface of the p-type silicon layer 107 (surface of the p-type well 109), for example. Further; a width dimension of the trench 123 is of the order of 0.3 to 0.4 μm, for example.

An is diffusion layer 129 (impurity diffusion layer) is formed in contact with the bottom of the trench 123 in the p-type silicon layer 107. A substantial concentration of the n-type impurities in the n+ diffusion layer 129 is 1×10¹⁸ cm⁻³, for example. A depletion layer (illustration is omitted) corresponding to a built-in potential has spread between the p-type silicon layer 107 and the n+ diffusion layer 129.

The n+ diffusion layer 129 is formed at a position deeper than the p-type well 109. The n+ diffusion layer 129 is arranged in the p-type silicon layer 107 at a position deeper than the p-n junction in the p-n junction photodiode 119.

In this example, the adjacent pixels 103 are separated by the trench 123, thereby to allow prevention of mixture of photo-charges generated in the adjacent pixels 103.

Further, in this example, with the n+ diffusion layer 129 provided at the bottom of the trench 123, it is possible to prevent mixture of the photo-charges generated in the adjacent pixels 103 to a deeper portion by means of the depletion layer between the p-type silicon layer 107 and the n+ diffusion layer 129.

There is a restriction on the depth of the trench 123 that can be formed. In this example, in order to prevent mixture of the photo-charges generated in the adjacent pixels 103 at a deeper position, not only the trench 123 but also the n+ diffusion layer 129 is further formed at the bottom of the trench 123.

Moreover, in this example. the adjacent pixels 103 are electrically separated by the trench 123. Accordingly, as compared to a technique used by the general CMOS semiconductor process is here adjacent pixels arc separated by an oxide film and a p-n junction, this example has an advantage of more easily shortening a distance between the adjacent pixels 103 and more easily making them finer.

With the above configuration, according to the semiconductor device of the present example, in the semiconductor device provided With the image sensor formed by arraying the photoelectric conversion elements on the semiconductor substrate, it is possible to prevent mixture of photo-charges between adjacent photoelectric conversion elements, and realize a finer design rule.

The above-described features can be achieved, even when he n-type and the p-type are replaced with each other.

Further, the trench 123 may be embedded with an insulating material such as a silicon oxide film or a silicon nitride film, instead of being embedded with the semiconductor material 127, When the trench 123 is to be embedded with the insulating material, it is possible to reduce the number of steps, for example, by one as compared to the case of performing a step of forming an insulating film on an inner wall of the trench 123, such as an oxidation step, so as to simplify the manufacturing process. It should be noted that the insulating material to be embedded into the trench 123 is not restricted to the silicon oxide film and the silicon nitride film.

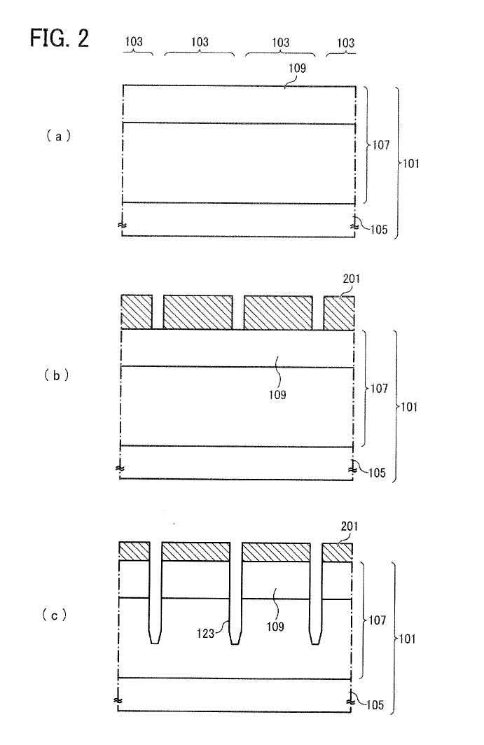

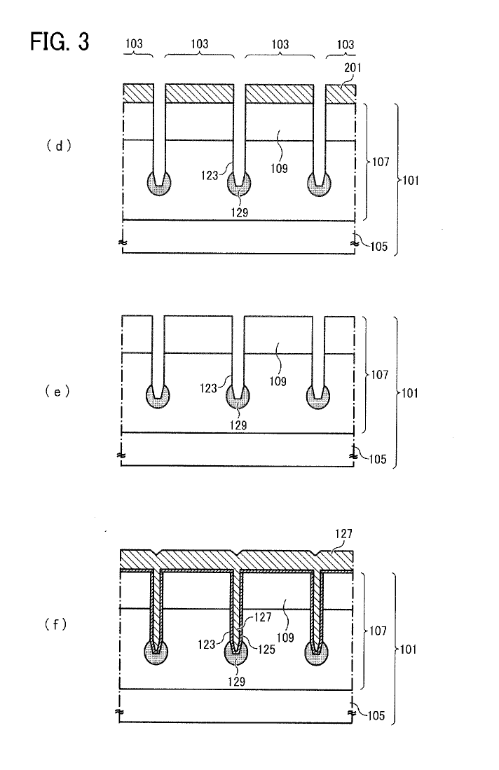

FIGS. 2 and 3 are sectional views for explaining a manufacturing process of manufacturing the example semiconductor device described with reference to FIG. 1. Steps (a) to (f) to be described below correspond to (a) to (f) in FIGS. 2 and 3. A step (g) will be described with reference to FIG. 1. It is to be noted that the manufacturing method described with reference to FIG. 1 is not restricted to an example of the manufacturing process described below.

(a) The semiconductor substrate 101, where the p-type silicon layer 107 is epitaxially grown on the p+ silicon substrate 105, is used. Boron is injected into the p-type silicon layer 107, including a region for forming the photoelectric conversion element, under conditions of 30 keV and 1×10¹³ cm⁻², for example. A drive-in diffusion is performed in a nitrogen gas atmosphere under conditions of 1150° C. and 1 hour, to diffuse boron injected into the p-type silicon layer 107 and form the p-type well 109.

(b) As a hard mark to form the trench for separating the adjacent pixels 103, a high temperature oxide (HTO) film 201 is formed with a thickness of the order of 400 nm on the p-type well 109. Using a photoengraving technique and an etching technique, the HTO film 201 in a region for forming the trench is removed, to form a hard mask having a trench corresponding to the above trench. Here, a width dimension of the trench of the HTO film 201 is set to the order of 0.3 to 0.4 μm.

(c) Using the hard mask made up of the HTO film 201, the trench 123 is formed in the p-type silicon layer 107 by the etching technique. For example, microwave plasma etching by use of SF, O₂ and Ar gases is performed, to process the trench 123 vertically to the surface of the p-type silicon layer 107. The depth of the trench 123 is of the order of 3.0 to 5.0 μm, for example. The width dimension of the trench 123 is of the order of 0.3 to 0.4 μm, for example. Here, since the hard mask is also etched, a thickness of the HTO film 201 has become as small as the order of 100 nm.

(d) Phosphorus is injected into the p-type silicon layer 107 with the HTO film 201 used as the mask. In order to vertically inject phosphorus into the surface of the p-type silicon layer 107, an injection angle is set to 0° under conditions of 15 keV and 5×10¹⁴ cm⁻², for example. Thereby, phosphorus as the n-type impurities is injected only to the bottom of the trench 123. The n+diffusion layer 129 in contact with the bottom of the trench 123 is formed in the p-type silicon layer 107.

(e) The HTO film 201 is removed by wet etching, for example. Oxidation treatment is performed, to oxidize the inner wall of the trench 123. For example, this oxidation treatment is performed by dry oxidation at 1050° C. under a condition of forming a silicon oxide film with a thickness of the order of 130 nm. Thereafter, the formed silicon oxide film is removed. By removing this silicon oxide film, a damage by microwave plasma etching can be suppressed. This can relax a crystal defect that may occur at the time of forming the trench 123, and prevent a leakage current from occurring at the p-n junction constituting the photodiode.

(f) In order to dielectrically separate the adjacent pixels 103, the oxidation treatment formed again, to form the insulating film 125 made up of a silicon oxide film on the inner wall of the trench 123. For example, the oxidation treatment is performed by wet oxidation at 850° C. under a condition of forming a silicon oxide film With a thickness of the order of 20 nm. In order to fill the trench 123, for example, a semiconductor material such as polysilicon with a thickness of the order of 800 nm is formed. The semiconductor material 127 is embedded into the trench 123 via the insulating film 125.

(g) The semiconductor material 127 is subjected to overall etching, to remove a redundant portion other than the semiconductor material 127 embedded into the trench 123. Thereafter, the p-n junction photodiode 119 and the transistor 121 for selectively outputting its signal are formed using the general CMOS semiconductor process (see FIG. 1).

Although the p-n junction photodiode 119 is used as the photoelectric conversion element in the above example, the photoelectric conversion element is not restricted to the p-n on photodiode in the semiconductor device of the present invention. In the semiconductor device of the present invention, the photoelectric conversion element may be another element such as a phototransistor, a PIN photodiode or an avalanche photodiode.

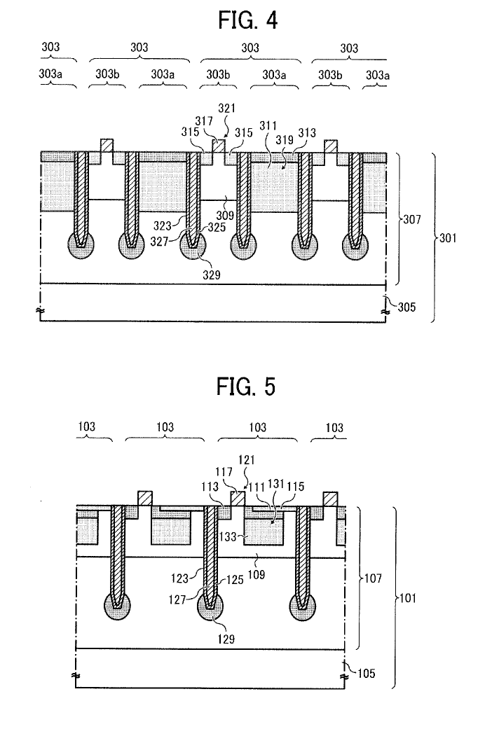

FIG. 4 is a schematic sectional view for explaining another example of semiconductor device, In this example, the phototransistor is provided as a photoelectric conversion element. A pixel 303 of a CMOS image sensor is formed on a semiconductor substrate 301.

A plane dimension of the pixel 303 is 5.0×5.0 μm, for example.

The semiconductor substrate 301 is formed of an n+ silicon substrate 305 and an n-type silicon layer 307 formed on the n+ silicon substrate 305, for example. The n+ silicon substrate 305 is a silicon substrate introduced with n-type impurities with a higher concentration as compared to the n-type silicon layer 307. The n-type silicon layer 307 is a silicon layer formed by epitaxial growth. A thickness of the n-type silicon layer 307 is from 10 to 20 μm, for example.

An n-type well 309 is formed on the surface side of the n-type silicon layer 307. A concentration of the n-type impurities in the n-type well 309 is higher than a concentration of the n-type impurities in the p-type silicon layer 307. A substantial concentration of the s-type impurities in the n-type well 309 is 1×10¹⁷ cm⁻³, for example. Further, a depth of the n-type well 309 is from 1 to 2 μm, for example.

Ina phototransistor region 303a of the pixel 303, a p-type diffusion layer 311 is formed on the surface side of the n-type silicon layer 307. The p-type diffusion layer 311 is formed deeper than the n-type well 309. A substantial concentration of the p-type impurities in the p-type diffusion layer 311 is 3×10¹⁵ cm⁻³, for example. A depth of the p-type diffusion layer 311 is from 1 to 2 μm from the surface of the n-type silicon layer 307, for example. The n-type well 309 is not formed in the phototransistor region 303a.

In the phototransistor region 303a of the pixel 303, an n-type diffusion layer 313 is formed on the surface side of the n-type silicon layer 307. The n+ diffusion layer 313 is formed shallower than the p-type diffusion layer 311. A substantial concentration of the n-type impurities in the n+ diffusion layer 313 is 3×10¹⁵ cm⁻, for example. Further, a depth of the diffusion layer 313 is from 0.2 to 0.3 μm from the surface of the n-type silicon layer 307, for example.

In an output selection switch 3036 of the pixel 303, a pair of p+ diffusion layers 315 is formed having an interval therebetween on the surface side of the n-type well 309. A substantial concentration of the p-type impurities in the p+ diffusion layer 315 is 5×10²⁰ cm⁻³ for example. Further, a depth of the p+ diffusion layer 315 is from 200 to 300 nm, for example.

In the output selection switch 303b of the pixel 303, a gate electrode 317 is formed above the n-type well 309 between the pair of p diffusion layers 315, via a gate insulating film (illustration is omitted).

In the pixel 303, a phototransistor 319 having the n-type silicon layer 307, the p-type diffusion layer 311 and the n+ diffusion layer 313 is formed in the phototransistor region 303a. The n-type silicon layer 307 constitutes a collector of the phototransistor 319. The p-type diffusion layer 311 constitutes a base of the phototransistor 319. The n+ diffusion layer 313 constitutes an emitter of the phototransistor 319. The n-type silicon layer 307 and the n+ silicon substrate 305 function as a common collector in the respective phototransistors 319 of a plurality of pixels 303. The phototransistor 319 is provided With p-n junctions respectively between the n-type silicon layer 307 and the p-type diffusion layer 311 and between the p-type diffusion layer 311 and the n+ diffusion layer 313.

Further, in the pixel 303, the transistor 321 made of a MOSFET having the pair of p+ diffusion layers 315 and the gate electrode 317 is formed in the output selection switch 303b. The transistor 321 functions as an output selection switch of the pixel 303. A trench 323 is formed in the semiconductor substrate 301 as surrounding a periphery of the pixel 303. The trench 323 separates the adjacent pixels 303. Further, the trench 323 separates the adjacent phototransistors 319. Moreover, the trench 323 separates the adjacent phototransistors 319 and the transistor 321 inside the pixel 303. It is to be noted that the phototransistor 319 and the transistor 321 may not be separated by the trench 323.

A semiconductor material 327 is embedded in the trench 323 via the insulating film 325. The insulating film 325 is a silicon oxide film, for example. The semiconductor material 327 is polysilicon, for example. It should be noted that an insulating material may be embedded into the trench 323 in place of the insulating film 325 and the semiconductor material 327. Examples of such an insulating material include a silicon oxide film and a silicon ride film.

For example, the trench 323 is formed at a larger depth than the n-type well 309. Further, the trench 323 is formed at a larger depth than the p-type diffusion layer 311 constituting the base of the phototransistor 319. A bottom of the trench 323 is formed in the n-type silicon layer 307 at a position having intervals with the n-type well 309 and the p-type diffusion layer 311, namely a position deeper than the p-n junction in the phototransistor 319. A depth of the trench 323 is from 3.0 to 5.0 μm from the surface of the n-type silicon layer 307, for example. Further, a width dimension of the trench 323 is of the order of 0.3 to 0.4 μm, for example.

An n+ diffusion layer 329 (impurity diffusion layer) is formed in contact with the bottom of the trench 323 in the n-type silicon layer 307. A substantial concentration of the n-type impurities in the diffusion layer 329 is 1×10¹⁸ cm⁻³, for example.

The n diffusion layer 329 is formed at a position deeper than the p-type diffusion layer 311. The n+ diffusion layer 329 is formed at a position having an interval with the p-type diffusion layer 311, namely a position deeper than the p-n junction in the phototransistor 319.

In this example, the adjacent pixels 303 are separated by the trench 323. thereby to allow prevention of mixture of photo-charges generated in the adjacent pixels 303.

Further, in this example, the n+ diffusion layer 329 is provided at the bottom of the trench 323. This prevents connection of depletion layers between the adjacent pixels 303. the depletion layer being formed by a built-in potential of the p-n junction formed between the base configured of the p-type diffusion layer 311 and the collector configured of the n-type silicon layer 307.

Moreover, in this example, the adjacent pixels 303 are electrically completely separated by the trench 323. Accordingly, as compared to the technique by the general CMOS semiconductor process where adjacent pixels are separated by an oxide film and a p-n junction, this example has an advantage of more easily shortening a distance between the adjacent pixels 303 and more easily making them finer.

Even when the n-type and the p-type are replaced with each other, the effects described referring to FIG. 4 can be obtained.

Moreover, in the semiconductor device of the present invention, the photoelectric conversion element may not he the p-n junction photodiode or the phototransistor, but be the PIN photodiode or the avalanche photodiode.

FIG. 5 is a schematic sectional view for explaining still another example of semiconductor device. In this example, the PIN photodiode is provided as a photoelectric conversion element. In FIG. 5, portions that serve the same functions as in FIG. 1 are provided with the same numerals, and descriptions of those portions are omitted.

The semiconductor device of this example is provided with a PIN photodiode 131 as the photoelectric conversion element in place of the p-n junction photodiode 119 of the example shown in FIG. 1. The PIN photodiode 131 has a p-type well 109, an is diffusion layer lit and an intrinsic region 133.

The p-type well 109 constitutes an anode of the PIN photodiode 131. The n+ diffusion layer 111 constitutes a cathode of the PIN photodiode 131.

The intrinsic region 133 is a genuine semiconductor region not substantially containing impurities. The intrinsic region 133 is arranged in contact with the p-type well 109 and the n+ diffusion layer 111 at a position shallower than the p-type well 109 and deeper than the n+ diffusion layer 111.

By the PIN photodiode 131 being used as the photoelectric conversion element, an output signal with respect to light can he made larger as compared to the case of the p-n junction photodiode being used as the photoelectric conversion element.

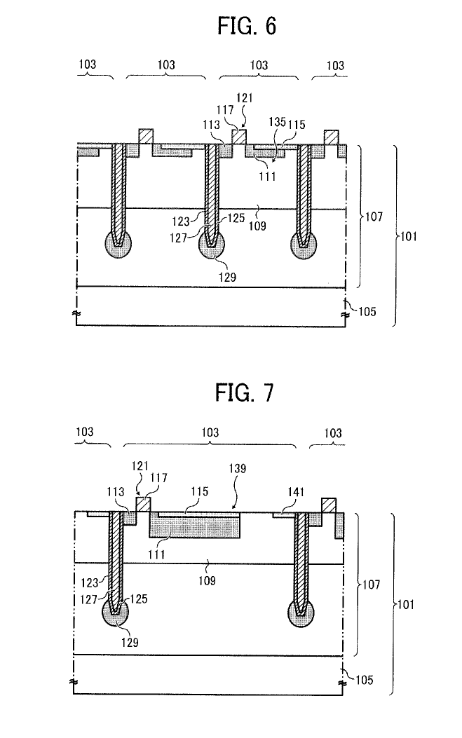

FIG. 6 is a schematic sectional view for explaining still another example of semiconductor device. In this example, the avalanche photodiode is provided as a photoelectric conversion element. In FIG. 6, portions that serve the same functions as in FIG. 1 are provided with the same numerals, and descriptions of those portions are omitted.

The semiconductor device of this example is provided with an avalanche photodiode 135 as the photoelectric conversion element in place of the p-n junction photodiode 119 of the example shown in FIG. 1. The avalanche photodiode 135 has a p+ silicon substrate 105, a p-type silicon layer 107, a p-type well 109 and an n+ diffusion layer 111.

The p+ silicon substrate 105, the p-type silicon layer 107 and the p-type well 109 constitute an anode of the avalanche photodiode 135. The n+ diffusion layer 111 constitutes a cathode of the avalanche photodiode 135.

Since a concentration of the impurities in the p-type silicon layer 107 is sufficiently love, a high electric field can be applied to the avalanche photodiode 135. In the state of a high electric field being applied, carriers are collided with atoms to bring about electron avalanche, which can lead to an increase in number of carriers. Hence the avalanche photodiode 135 can make an output signal with respect to light larger.

By the avalanche photodiode 135 being used as the photoelectric conversion element, the output signal with respect to light can be made larger as compared to the case of the p-n junction photodiode being used as the photoelectric conversion element.

Moreover, although the vertical photodiode and phototransistor have been used in the examples described above, the photoelectric conversion element may be a lateral photodiode or phototransistor in the semiconductor device of the present invention.

FIG. 7 is a schematic sectional view for explaining still another example of semiconductor device. In this example, the lateral p-n junction photodiode is provided as a photoelectric conversion element. In FIG. 7, portions that serve the same functions as in FIG. 1 are provided with the same numerals, and descriptions of those portions arc omitted.

The semiconductor device of this example is provided with a lateral p-n junction photodiode 139 as the photoelectric conversion element in place of the vertical p-n junction photodiode 119 of the example shown in FIG. 1. The lateral junction photodiode 139 has a p-type well 109 and an n+ diffusion layer 111.

The p-type well 109 constitutes an anode of the p-n junction photodiode 139. The diffusion layer 111 constitutes a cathode of the p-n junction photodiode 139. In this example, the p-type silicon layer 107 and the silicon substrate 105 do not constitute the anode of the p-n junction photodiode 139.

A p+ diffusion layer 141 is arranged on the surface side of the p-type well 109. The p+ diffusion layer 141 is arranged having intervals with the n+ diffusion layer 111, the n+ diffusion layer 113 and the p+ diffusion layer 115. The p+ diffusion layer 141 is used as an anode contact of the p-n junction photodiode 139.

As thus described, in the semiconductor device of the present invention, the photoelectric conversion element may be the lateral p-n junction photodiode 139.

It is to be noted that in the semiconductor device of the present invention, the photoelectric conversion element may be a lateral PIN photodiode or a lateral avalanche photodiode.

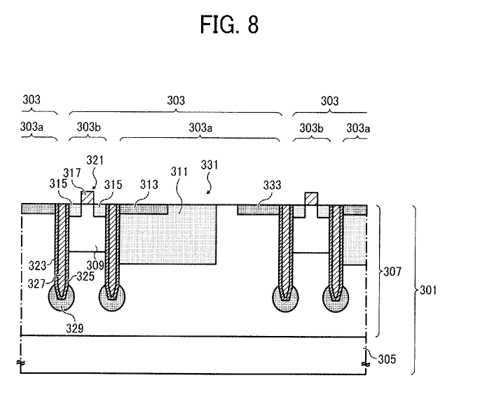

FIG. 8 is a schematic sectional view for explaining still another example of semiconductor device. In this example, the lateral phototransistor is provided as the photoelectric phototransistor. In FIG. 8, portions that serve the same functions as in FIG. 4 are provided with the same numerals, and descriptions of those portions are omitted.

The semiconductor device of this example is provided with a lateral phototransistor 331 as the photoelectric conversion element in a phototransistor region 303a in place of the vertical phototransistor 319 of the example shown in FIG. 4. The lateral phototransistor 331 has an n-type silicon layer 307, a p-type diffusion layer 311 and an n+ diffusion layer 313.

The n-type silicon layer 307 constitutes a collector of the phototransistor 331. The p-type diffusion layer 311 constitutes a base of the phototransistor 331. The n+ diffusion layer 313 constitutes an emitter of the phototransistor 331. In this example, the n+ silicon substrate 305 does not constitute the collector of the phototransistor 331.

In the phototransistor region 303a, an n-type diffusion layer 333 is arranged on the surface side of the n-type silicon layer 307. The n-type diffusion layer 333 is arranged having intervals with the p-type diffusion layer 311 and the diffusion layer 313. The n-type diffusion layer 333 is used as a collector contact of the phototransistor 331.

As thus described, in the semiconductor device of the present invention, the photoelectric conversion element may be the lateral phototransistor 331.

Although the examples of the present invention have been described above, each of the numerical values, the materials, the arrangements, the numbers and the like in the above examples is an instance. The present invention is not restricted thereto, and a variety of changes can be made within the scope of the present invention recited in the claims.

For example, although the silicon substrate is used as the semiconductor substrate in the above examples, the semiconductor substrate may be a semiconductor substrate other than the silicon substrate in the semiconductor device of the present invention. Moreover, in the semiconductor device of the present invention, the configuration of the photoelectric conversion element is not restricted to the configurations of the photodiodes shown in FIGS. 1, 5, 6 and 7, and to the configurations of the phototransistors shown in FIGS. 4 and 8.

Numerous additional modifications and variations are possible in light of the above teachings. It is therefore to be understood that within the scope of the appended claims, the disclosure of the present invention may be practiced otherwise than as specifically described herein. For example, elements and/or features of different illustrative embodiments may be combined with each other and/or substituted for each other within the scope of this disclosure and appended claims.

For example, according to one example of semiconductor device, the trench is formed in the semiconductor substrate as surrounding a periphery of the photoelectric conversion element. However, the trench may not surround the periphery of the photoelectric conversion element. The trench may only be arranged at least at a position allowing prevention of mixture of photo-charges between the adjacent photoelectric conversion elements.

In the above-described example, the photoelectric conversion element is any of a p-n junction photodiode, a p-intrinsic-n (PIN) photodiode and an avalanche photodiode. In the case of the photoelectric conversion clement being the PIN photodiode or the avalanche photodiode, an output signal with respect to light can be made larger as compared to the case of the photoelectric conversion element being the p-n junction photodiode.

Further, in the above-described example, a concentration of an injected type in the impurity diffusion layer is lower than a concentration of the injected type in the diffusion layer which is formed on the surface side of the semiconductor substrate and constitutes an anode or a cathode of the photodiode. Accordingly, even when the impurity diffusion layer and the cathode or the anode of the photodiode come into contact with each other, high-concentration impurity regions do not come into contact with each other, and it is thus possible to prevent occurrence of a junction leakage current at that junction portion.

In the above-described example, the photoelectric conversion element is a phototransistor. Using the phototransistor as the photoelectric conversion element can make the output signal larger due to amplification of the transistor.

Further, in the above-described example, the concentration of the injected type in the impurity diffusion layer is lower than a concentration of the injected type in a diffusion layer which constitutes an emitter of the phototransistor. Accordingly, even when the impurity diffusion layer and a base of the phototransistor come into contact with each other, high-concentration impurity regions do not come into contact with each other, and it is thus possible to prevent occurrence of a junction leakage current at that junction portion.

In the above-described example, a silicon oxide film or a silicon nitride film is embedded in the trench. Accordingly, it is possible to omit one oxidation step as compared to the case of forming an oxide film on an inner wall of the trench by the oxidation step, so as to simplify the manufacturing process. It is to be noted that a material to be embedded into the trench is not restricted to these.

What is claimed is:

1. A semiconductor device comprising:
a semiconductor substrate;
a plurality of photoelectric conversion elements arranged on the semiconductor substrate, to collectively form an image sensor;
a plurality of trenches each formed between the photoelectric conversion elements adjacent to each other; and
a plurality of impurity diffusion layers each provided at a bottom of the trench at a position deeper than a p-n junction of the photoelectric conversion clement.

2. The semiconductor device according to claim 1, wherein the trench is formed in the semiconductor substrate so as to surround a periphery of the photoelectric conversion clement.

3. The semiconductor device according to claim 1, wherein photoelectric conversion element is a p-n junction photodiode.

4. The semiconductor device according to claim 1 where he photoelectric conversion element is a PIN photodiode.

5. The semiconductor device according to claim 1, wherein the photoelectric conversion element is an avalanche photodiode.

6. The semiconductor device according to claim 3, wherein a concentration of an injected type in the impurity diffusion layer is lower than a concentration of the injected type in the diffusion layer which is formed on the surface side of the semiconductor substrate and constitutes an anode or a cathode of the photodiode.

7. The semiconductor device according to claim 1 wherein the photoelectric conversion element is a phototransistor.

8. The semiconductor device according to claim 7, wherein the concentration of the injected type in the impurity diffusion layer is lower than a concentration of the injected type in a diffusion layer which is formed on the surface side of the semiconductor substrate and constitutes an emitter of the phototransistor.

9. The semiconductor device according to claim 1, wherein a silicon oxide film embedded in the trench.

10. The semiconductor device according to claim 1, wherein a silicon nitride film is embedded in the trench.

11. The semiconductor device according to claim 2, wherein the photoelectric conversion element is a p-n junction photodiode.

12. The semiconductor device according to claim 2, wherein the photoelectric conversion element is a PIN photodiode.

13. The semiconductor device according to claim 2. wherein the photoelectric conversion element is an avalanche photodiode.

14. The semiconductor device according to claim 4, wherein a concentration of an injected type in the impurity diffusion layer is lower than a concentration of the injected type in the diffusion layer which is formed on the surface side of the semiconductor substrate and constitutes an anode or a cathode of the photodiode.

15. The semiconductor device according to claim 5, wherein a concentration of an injected type in the impurity diffusion layer is lower than a concentration of the injected type in the diffusion layer which is formed on the surface side of the semiconductor substrate and constitutes an anode or a cathode of the photodiode.

16. The semiconductor device according to claim 2, wherein the photoelectric conversion element is a phototransistor.

17. The semiconductor device according to claim 2 wherein a silicon oxide film is embedded in the trench.

18. The semiconductor device according to claim 2, wherein a silicon nitride film is embedded in the trench.

19. The semiconductor device according to claim 16, wherein he concentration of the injected type in the impurity diffusion layer is lower than a concentration of the injected type in a diffusion layer which is formed on the surface side of the semiconductor substrate and constitutes an emitter of the phototransistor.

20. The semiconductor device according claim 6, wherein a silicon oxide film is embedded in the trench.
